(19) United States
(12) Patent Application Publication
(10) Pub. No.: US 2015/0303171 A1
(43) Pub. Date: Oct. 22, 2015

(54) SYSTEMS AND METHODS FOR CARRYING SINGULATED DEVICE PACKAGES

(71) Applicant: Cirrus Logic, Inc., Austin, TX (US)

(72) Inventors: David T. Patten, Austin, TX (US); Jason Hwang, Taipei (TW); Joseph Martin Gabriel, III, Austin, TX (US)

(21) Appl. No.: 14/690,763

(22) Filed: Apr. 20, 2015

Related U.S. Application Data
(60) Provisional application No. 61/982,744, filed on Apr. 22, 2014.

(51) Int. Cl. H01L 23/00; H01L 21/683

(52) U.S. Cl. CPC H01L 24/97; H01L 21/6836; H01L 24/83; H01L 2224/83005

(57) ABSTRACT

In accordance with embodiments of the present disclosure, a method may include providing a substrate adapted for use in wafer processing equipment, wherein the substrate includes an adhesive applied thereto. The method may also include reconstituting a plurality of device packages onto the substrate. In accordance with these and other embodiments of the present disclosure, an apparatus may include a substrate adapted for use in wafer processing equipment, an adhesive applied to the substrate, and a plurality of device packages reconstituted onto the substrate.

### RELATED APPLICATIONS

The present application claims priority from U.S. Provisional Patent Application No. 61/982,744 filed on Apr. 22, 2014, which is incorporated herein by reference.

### FIELD OF DISCLOSURE

The present disclosure relates in general to processing and manufacturing of integrated circuit device packages.

### BACKGROUND

Integrated circuits are manufactured in a number of discreet steps using a variety of processes and equipment. Due to the differences in these processes and economic factors, different processes may be carried out at different locations throughout the globe.

Semiconductor material may be initially grown in a single crystal in a melt process which typically may be performed in a specialized facility, usually by a dedicated vendor for such processes. Single crystals are then sliced into wafers which may then be further processed in a “fab” or fabrication facility. In the fab, the actual circuits may be formed on the semiconductor wafer using a variety of known semiconductor processing processes.

Once each wafer has been formed into circuits, it may then be sent to a facility for final machining, testing, singulating (e.g., sawing or separating into individual circuits), and packaging. In singulation, a wafer may be sawed or broken into a number of individual chips or circuits. In some cases, each chip may then be mounted in a frame or carrier with electrical leads wired-bonded from the carrier to the chip at discrete pad locations and then be packaged (encapsulated) and labeled to form a final product. In other cases, a chip may not be mounted or encapsulated in another package, but may comprise a wafer-level chip scale package or similar package which serves as a standalone device.

During manufacturing, a device package, whether encapsulated or unencapsulated, may be tested at a number of different stages to ensure that the circuit formed thereon functions correctly. For example, a device may be subject to testing including pre-conditioning, autoclaving, temperature cycling testing, high-temperature soak testing, un-biased or biased highly-accelerated stress testing, temperature humidity bias testing, and other stress and functionality testing.

A wafer-level chip-scale package (WLCSP) is generally moisture-sensitivity level 1 and 260° C. compliant and is often typically robust through many of such package-level stresses, but has features intrinsic to it that often render it difficult for testing and qualification. For example, WLCSPs may have small form factors rendering them difficult to handle, may come in non-standard sizes necessitating high tooling costs and single-use hardware, may include non-robust features in a singulated form which may lead to re-distribution layers, die perimeters, and exposed bumps being damaged, and may have a small pitch (e.g., 0.4 mm and smaller) rendering them difficult to support with normal burn-in hardware and processes.

Existing industry solutions for addressing such problems include qualifying by encapsulating the WLCSP for purposes of qualification (e.g., encapsulating the WLCSP in a mold compound or other epoxy). Encapsulating the WLCSP has the advantage of protecting the WLCSP from handling damage. However, encapsulating the WLCSP for purposes of qualification does not represent the true end-product in stress testing, for many reasons. First, a WLCSP may not be encapsulated in its end use, and any package encapsulating a WLCSP for testing may have test equipment read points which would necessarily have different electrical characteristics than the unencapsulated WLCSP. Second, test hardware and test programs used for such read points may not be used in production of the WLCSP, which may require custom set up for testing. Third, because the package encapsulating the WLCSP for testing does not represent the true end-product, deficiencies of the package may indicate false failures of an otherwise satisfactory WLCSP. Fourth, while a WLCSP may be capable of testing at certain moisture sensitivity levels and above particular temperatures (e.g., 260° C.), a package encapsulating a WLCSP for testing may not be so capable.

Another industry solution includes flip-chip mounting the WLCSP on a substrate dedicated to the single WLCSP but not encapsulating it with an over-mold as would be in the case of encapsulation. While such approach more accurately represents end-use conditions as compared to encapsulating the WLCSP, such approach may not protect the WLCSP from handling during testing.

### SUMMARY

In accordance with the teachings of the present disclosure, one or more disadvantages and problems associated with existing approaches to testing and qualifying device packages may be reduced or eliminated.

In accordance with embodiments of the present disclosure, a method may include providing a substrate adapted for use in wafer processing equipment, wherein the substrate includes an adhesive applied thereto. The method may also include reconstituting a plurality of device packages onto the substrate.

In accordance with these and other embodiments of the present disclosure, an apparatus may include a substrate adapted for use in wafer processing equipment, an adhesive applied to the substrate, and a plurality of device packages reconstituted onto the substrate.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a substrate for use as a device carrier, in accordance with embodiments of the present disclosure;

FIG. 2 illustrates a flow chart of an example method for reconstituting and testing device packages using a substrate as a device carrier, in accordance with embodiments of the present disclosure;

FIG. 3 illustrates an example of wafer processing equipment that may be used to handle the substrate of FIG. 1, in accordance with embodiments of the present disclosure; and

FIG. 4 illustrates an example of a testing device that may be used in connection with the wafer processing equipment depicted in FIG. 3, in accordance with embodiments of the present disclosure.

### DETAILED DESCRIPTION

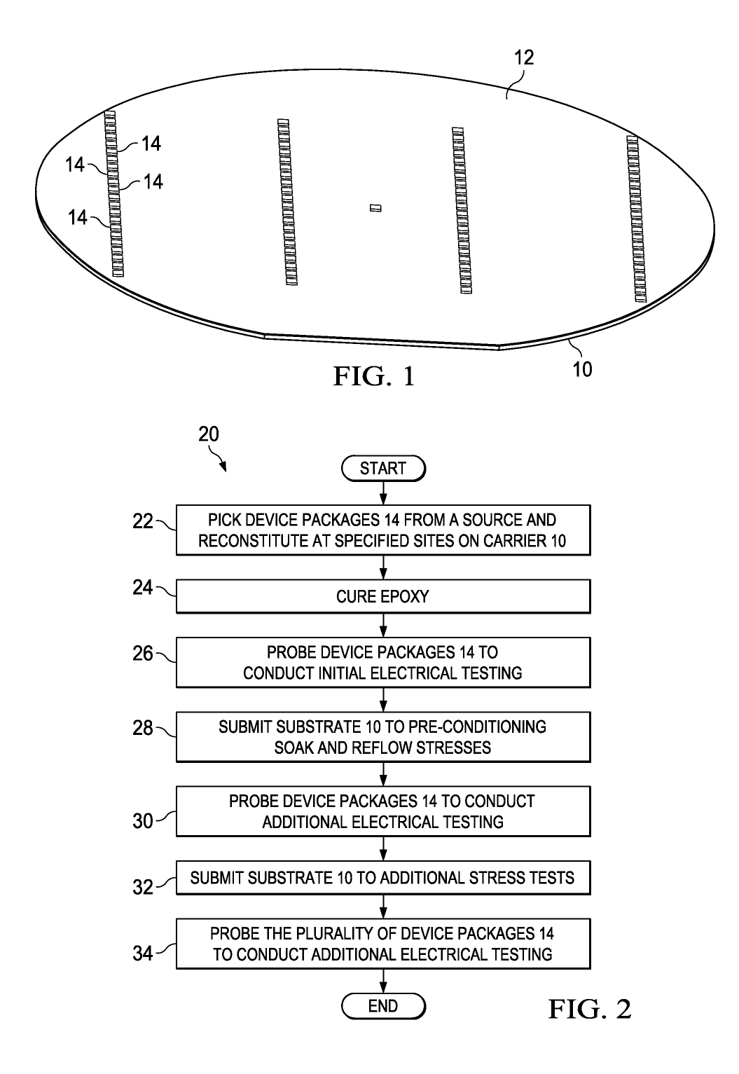

FIG. 1 illustrates a substrate 10 for use as a device carrier, in accordance with embodiments of the present disclosure. As shown in FIG. 1, substrate 10 may include an adhesive 12 applied to a surface thereof, and a plurality of device packages 14 reconstituted on substrate 10, adhered to substrate 10 by adhesive 12.

Substrate 10 may comprise any suitable substrate for carrying device packages for testing and qualification. In some embodiments, substrate 10 may be adapted for use in wafer processing equipment and thus may accordingly be sized and/or shaped similar to a semiconductor wafer that may be used in wafer processing equipment. In some embodiments, substrate 10 may comprise a semiconductor wafer (e.g., a silicon wafer). In other embodiments, substrate 10 may comprise a ceramic wafer. However, embodiments of the present disclosure are not limited to substrate 10 comprising a semiconductor wafer or a ceramic wafer, and may comprise any suitable substrate in accordance with this disclosure.

Adhesive 12 may comprise any suitable adhesive material for coupling device packages 14 to substrate 10. For example, in some embodiments, adhesive 12 may comprise a layer or film of dual-sided adhesive tape. In other embodiments, adhesive 12 may comprise an epoxy that is cured after device packages 14 are reconstituted on substrate 10 in order to adhere device packages 14 to substrate 10. In yet other embodiments, adhesive 12 may comprise a material for providing a temporary bond between device packages 14 and substrate 10, which may allow for efficient removal of device packages 14 from substrate 10 (e.g., in order to remove one or more device packages 14 for failure analysis). Examples of materials for providing a temporary bond include high-temperature films of polyimide coated on each side with a silicone adhesive and controlled release tapes designed for temporary bonding during grinding and dicing of semiconductor wafers.

In the embodiments represented by FIG. 1, the plurality of device packages 14 comprises wafer-level chip-scale packages (WLCSPs). However, any suitable device package may be reconstituted on substrate 10 in a manner similar or identical to that described herein, including without limitation a leadframe-based package, a laminate-based package, a hermetic package, a bare-die package, a fan-out wafer-level chip-scale package, etc. In some embodiments, reconstituting the plurality of device packages 14 on substrate 10 comprises retrieving each of the plurality of device packages 14 from a singulated source wafer on a wafer frame and placing each of the plurality of device packages 14 on substrate 10. In other embodiments, reconstituting the plurality of device packages 14 on substrate 10 comprises retrieving each of the plurality of device packages from a source carrier tape and placing each of the plurality of device packages on substrate 10.

Thus, as described above, an apparatus may include substrate 10 adapted for use in wafer processing equipment, with adhesive 12 applied to substrate 10, and a plurality of device packages 14 reconstituted onto substrate 10.

In some embodiments, particularly in those in which substrate 10 is used to carry WLCSPs, a material comprising substrate 10 may be selected such that a coefficient of thermal expansion of substrate 10 is approximately equal to that of a coefficient of thermal expansion of the plurality of device packages 14. For example, in embodiments in which device packages 14 comprise silicon, substrate 10 may also comprise silicon or comprise a material having a coefficient of thermal expansion approximately equal to that of silicon. By matching thermal expansion properties of device packages 14 and substrate 10, substrate 10 may be compliant with thermal stresses placed on device packages 14 during testing and qualification, which may reduce the likelihood of damage to device packages 14 during testing and qualification.

By using substrate 10 as a device package carrier in the manner described herein, a carrier is provided that may withstand all stresses placed on device packages during testing and qualification, while being compatible with existing assembly and test equipment and supporting automated testing using existing production hardware and test programs. Such a carrier may be capable of retaining and supporting device packages through all handling, stressing, and shipping steps to reduce device damage. Such a carrier may also present devices with sufficient accuracy to test equipment in order to support electrical testing on all of its pins, and may be generically able to support many device variations.

FIG. 2 illustrates a flow chart of an example method 20 for reconstituting and testing device packages using a substrate as a device carrier, in accordance with embodiments of the present disclosure. According to certain embodiments, method 20 may begin at step 22. As noted above, teachings of the present disclosure may be implemented in a variety of configurations of substrate 10 as shown in FIG. 1. As such, the preferred initialization point for method 20 and the order of the steps comprising method 20 may depend on the implementation chosen.

At step 22, handling equipment may pick a device package 14 from a source (e.g., from a singulated source wafer on a wafer frame or from a source carrier tape comprising singulated device packages 14) and reconstitute it at a specified site on substrate 10. Step 22 may be repeated for each device package 14 to be reconstituted on substrate 10.

At step 24, in embodiments in which adhesive 12 comprises an epoxy, handling equipment may provide heat or other stimulus to cure the epoxy to adhere device packages 14 to substrate 10. In embodiments in which another type of adhesive is used (e.g., dual-sided tape or film), step 24 may be skipped, and step 26 may proceed after step 22.

At step 26, automated test equipment may probe the plurality of device packages 14 adhered to substrate 10 in order to conduct initial electrical testing (e.g., “TO” of “time zero” probing) of device packages 14.

At step 28, handling equipment may submit substrate 10 to pre-conditioning soak and reflow stresses, after which, at step 30, automated test equipment may again probe the plurality of device packages 14 to conduct additional electrical testing (e.g., to determine which of device packages 14 survived stresses of pre-conditioning soak and reflow).

At step 32, handling equipment may again submit substrate 10 to other stress tests, after which, at step 34, automated test equipment may again probe the plurality of device packages 14 to conduct additional electrical testing (e.g., to determine which of device packages 14 survived the additional stress testing).

Although FIG. 2 discloses a particular number of steps to be taken with respect to method 20, it may be executed with greater or fewer steps than those depicted in FIG. 2. In addition, although FIG. 2 discloses a certain order of steps to be taken with respect to method 20, the steps comprising method 20 may be completed in any suitable order.

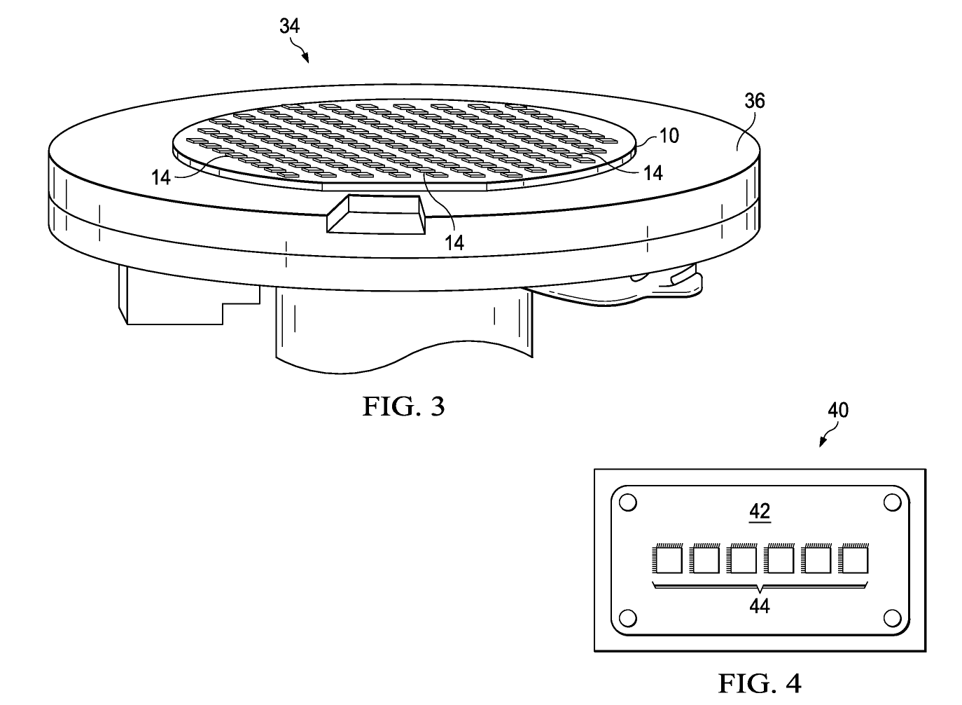

FIG. 3 illustrates an example of wafer processing equipment 34 that may be used to process and/or handle substrate 10, in accordance with embodiments of the present disclosure. In particular, FIG. 3 depicts wafer processing equipment 34 as a test frame. As shown in FIG. 3, wafer processing equipment 34 may include a chuck 36 sized and shaped to accommodate and hold wafers in a desired position for testing by a testing device (e.g., a multi-point test probe, such as that depicted in FIG. 4 below). During electrical testing of a typical wafer with devices fabricated thereon, a testing device may, under direction of a program of instructions, test electrical properties of the various circuits fabricated upon the wafer. Because substrate 10 described herein may be sized and/or shaped similar to a semiconductor wafer that may be used in wafer processing equipment, a substrate 10 carrying singulated device packages 14 may also be placed in chuck 36 and the various singulated device packages 14 may be subject to electrical testing by a testing device in a manner similar to that of testing of unsingulated devices on a wafer.

FIG. 4 illustrates an example of a testing device 40 that may be used in connection with the wafer processing equipment depicted in FIG. 3, in accordance with embodiments of the present disclosure. In particular, FIG. 4 depicts test device 40 as including a multi-point test probe head 42. As shown in FIG. 4, test probe head 42 may include a printed circuit board having a plurality of test contacts 44, each contact 44 including one or more test sites. For example, a test site may be a miniature probe or metallic contact configured to touch down on a semiconductor die at a predetermined position for collecting information about the operability of a semiconductor die, wherein such information may be relayed back to a computer or other equipment for processing. Because substrate 10 described herein may be sized and/or shaped similar to a semiconductor wafer that may be used in wafer processing equipment, singulated device packages 14 may be subject to electrical testing by a testing device identical or similar to test device 40.

Although FIGS. 3 and 4 depict a wafer prober chuck for use with a testing device as an example of wafer processing equipment, wafer processing equipment may also include any system, device, or apparatus used in fabrication, transport, storage, and/or testing of semiconductor wafers comprising unsingulated and/or singulated integrated circuits. Examples of such equipment may include, without limitation, wafer probers, frame probers, test probers, die sorters, automated optical inspection equipment, and wafer mounters.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the invention and the concepts contributed by the inventor to furthering the art, and are construed as being without limitation to such specifically recited examples and conditions. Although embodiments of the present inventions have been described in detail, it should be understood that various changes, substitutions, and alterations could be made hereto without departing from the spirit and scope of the disclosure.

What is claimed is:

1. A method comprising:
providing a substrate adapted for use in wafer processing equipment, wherein the substrate includes an adhesive applied thereto; and
reconstituting a plurality of device packages onto the substrate.

2. The method of claim 1, wherein the substrate comprises a semiconductor wafer.

3. The method of claim 2, wherein the substrate comprises a silicon wafer.

4. The method of claim 1, wherein the substrate comprises a ceramic wafer.

5. The method of claim 1, wherein a coefficient of thermal expansion of the substrate is approximately equal to that of a coefficient of thermal expansion of the plurality of device packages.

6. The method of claim 1, wherein reconstituting comprises retrieving each of the plurality of device packages from a singulated source wafer on a wafer frame and placing each of the plurality of device packages on the substrate.

7. The method of claim 1, wherein reconstituting comprises retrieving each of the plurality of device packages from a source carrier tape and placing each of the plurality of device packages on the substrate.

8. The method of claim 1, wherein the adhesive comprises a layer of dual-sided adhesive tape.

9. The method of claim 1, wherein the adhesive comprises an epoxy.

10. The method of claim 9, further comprising curing the epoxy.

11. The method of claim 1, wherein the adhesive comprises a material for providing a temporary bond between the device packages and the substrate.

12. The method of claim 1, wherein the device packages comprise wafer-level chip-scale packages.

13. The method of claim 1, wherein the device packages comprise at least one package comprising a leadframe-based package, a laminate-based package, a hermetic package, a bare-die package, and a fan-out wafer-level chip-scale package.

14. An apparatus comprising:
a substrate adapted for use in wafer processing equipment;
an adhesive applied to the substrate; and
a plurality of device packages reconstituted onto the substrate.

15. The apparatus of claim 14, wherein the substrate comprises a semiconductor wafer.

16. The apparatus of claim 15, wherein the substrate comprises a silicon wafer.

17. The apparatus of claim 14, wherein the substrate comprises a ceramic wafer.

18. The apparatus of claim 14, wherein a coefficient of thermal expansion of the substrate is approximately equal to that of a coefficient of thermal expansion of the plurality of device packages.

19. The apparatus of claim 14, wherein each of the plurality of device packages comprises a singulated device from a source wafer comprising a plurality of unsingulated devices.

20. The apparatus of claim 14, wherein the adhesive comprises a layer of dual-sided adhesive tape.

21. The apparatus of claim 14, wherein the adhesive comprises an epoxy.

22. The apparatus of claim 14, wherein the adhesive comprises a material for providing a temporary bond between the device packages and the substrate.

23. The apparatus of claim 14, wherein the device packages comprise wafer-level chip-scale packages.

24. The apparatus of claim 14, wherein the device packages comprise at least one package comprising a leadframe-based package, a laminate-based package, a hermetic package, a bare-die package, and a fan-out wafer-level chip-scale package.
